(19) United States
(12) Patent Application Publication
(10) Pub. No.: US 2012/0152315 A1
(43) Pub. Date: Jun. 21, 2012

(54) Solar energy collector

(76) Inventor: Yi Pang, Olney, MD (US)

(21) Appl. No.: 13/326,416

(22) Filed: Dec. 15, 2011

Related U.S. Application Data
(60) Provisional application No. 61/423,643, filed on Dec. 16, 2010.

(51) Int. Cl. H01L 31/052; H01L 31/0232

(52) U.S. Cl. 136/246; 136/259

(57) ABSTRACT

A solar collector comprises a concentrator that focuses sunlight into concentrated light and a light receiver. The light receiver includes a concave photovoltaic cell structure connected to reflecting surfaces. The concave photovoltaic cell structure is made of a concave photovoltaic cell, or multiple flat photovoltaic cells forming a concave shape, or a photovoltaic cell and its mirror images forming a virtual concave shape. The reflecting surfaces are oriented to reflect light onto the photovoltaic cell. Each reflecting surface may be a mirrored wall of a mirror or the side-wall of a reflecting prism. A heat pipe may be attached to the light receiver and a transparent container may encase the concentrator and the light receiver. The container may be sealed from the environment, contain an insulating gas, or be held under a vacuum.

### CROSS-REFERENCE TO RELATED APPLICATIONS

This application claims the benefit of U.S. Provisional Application No. 61/423,643, filed 16 Dec. 2010, which is hereby incorporated by reference herein.

### TECHNICAL FIELD

In the field of photovoltaics and solar thermal, a solar energy device for the generation of electric and thermal energy upon exposure to light to photovoltaic cells uses a concentrator sending light to a concave-light-receiving surface formed by one or more photovoltaic cells with an appended mirrored structure.

### SUMMARY OF INVENTION

A solar collector comprises two components: a concentrator that focuses sunlight to create concentrated light; and a light receiver that includes a concave photovoltaic cell structure connected to reflecting surfaces. The concave photovoltaic cell structure is made of a concave photovoltaic cell, or multiple flat photovoltaic cells forming a concave shape, or a photovoltaic cell and its mirror images forming a virtual concave shape. The reflecting surfaces are oriented to reflect light onto the photovoltaic cells. Each reflecting surface may be a mirrored wall of a mirror or the side-wall of a reflecting prism. A heat pipe may be attached to the light receiver and a container may encase the concentrator and the light receiver. The container may be sealed from the environment, contain an insulating gas, or be held under a vacuum. The container must have a transparent wall to allow sunlight to enter.

### Technical Problem

Existing concentrated photovoltaic systems do not achieve maximal potential efficiency of the photovoltaic cells, also known as solar cells, because when the sunlight is concentrated, the rays are no longer parallel, but rather the rays have a large diverse angle from the normal with respect to the photovoltaic cells. The state-of-the-art best efficiency solar cells require light to impinge more or less perpendicularly and uniformly to the entire solar cell surface in order to achieve their potential efficiency. Inventor's previous patent application US2011/0226308 on a solar energy hybrid module addressed efficiency issues by employing solar cells attached to polygon-rod heat pipe. While an improvement to the state of the art, that configuration did not address the problem occurring when the orientation of the solar energy collector is not perfect towards the sun and some of the concentrated light misses the solar cells. These problems may be characterized as a loss of light problem that prevents achieving a maximal efficiency of the solar energy collector.

### Solution to Problem

The solution to the problem is a solar energy collector with a light receiver including one or more photovoltaic cells connected to reflective surfaces. The photovoltaic cell is concave, or multiple photovoltaic cells, or one photovoltaic cell and its images form a concave light receiving surface onto which the concentrated sunlight can impinge normally and uniformly when diverge from its focal point, with reflective surfaces capturing concentrated sunlight that would otherwise be lost. This otherwise lost concentrated sunlight is redirected to the solar cells and is especially useful when the solar energy collector is not perfectly oriented to the sun for concentrated light to impinge completely on the solar cells.

### Advantageous Effects of Invention

The solar energy collector will have a maximized efficiency by ensuring the concentrated sunlight impinges uniformly to the solar cell and normal to its surface.

With reflecting surfaces capturing the leaking sunlight and redirect it to the solar cells, it is tolerant to less than ideal orientation and tracking errors.

The solar energy collector is also tolerant to less than ideally manufactured components, such as the concentrator. Greater deviations away from a parabolic shape can be tolerated, thus making manufacturing of the solar energy collector easier and less expensive.

### BRIEF DESCRIPTION OF DRAWINGS

The drawings illustrate preferred embodiments of the method of the invention and the reference numbers in the drawings are used consistently throughout. New reference numbers in FIG. 2 are given the 200 series numbers. Similarly, new reference numbers in each succeeding drawing are given a corresponding series number beginning with the figure number.

FIG. 1 is a cross-sectional view of a solar collector including a concentrator and a light receiver forming a concave light-receiving volume created by a concave photovoltaic cell with appended reflecting surfaces.

FIG. 2 illustrates a circular three-dimensional concentrator.

FIG. 3 illustrates a square three-dimensional concentrator.

FIG. 4 illustrates a hexagonal three-dimensional concentrator.

FIG. 5 is a cross-sectional view of a solar collector including a concentrator and a light receiver having an alternative concave light-receiving surface created by flat photovoltaic cells and appended reflecting surfaces.

FIG. 6 illustrates a hexagonal-base polyhedron receiving volume.

FIG. 7 illustrates a rectangular-base polyhedron receiving volume.

FIG. 8 illustrates an alternative hexagonal-base polyhedron receiving volume.

FIG. 9 illustrates an alternative rectangular-base polyhedron receiving volume paired with a Fresnel lens.

FIG. 10 is a cross-sectional view of a solar collector including a concentrator and a light receiver forming a concave light-receiving volume occupied by a reflecting prism.

FIG. 11 is a cross-sectional view of a solar collector with a concave arrangement of three photovoltaic cells with appended mirrors.

FIG. 12 is a cross-sectional view of a solar collector with a virtual concave arrangement of a photovoltaic cell with its mirror images that form a concave light-receiving surface similar to FIG. 11.

FIG. 13 is an end view of a solar collector including a concentrator and a light receiver enclosed in a transparent tube and attached to a heat pipe.

FIG. 14 is an end view of a solar collector enclosed in a transparent tube with photovoltaic cells and appended reflecting prism attached to a square heat pipe.

FIG. 15 is a perspective of a solar collector in a transparent tube.

FIG. 16 is a perspective view of the light receiving end of an exemplary photovoltaic cell with 2 mirrors extending downwardly for 2 edges of the photovoltaic cell, having application with an elongated concentrator like the one in FIG. 15.

FIG. 17 is a perspective of a light receiver with a photovoltaic cell with 4 mirrors extending downwardly from all 4 edges of the photovoltaic cell, and having application with a 3D concentrator such as illustrated in FIG. 18.

FIG. 18 is a side view of a solar collector consisting of an array of 3D concentrators mounted within an insulated container with a transparent top and a square heat pipe.

FIG. 19 shows a linear Fresnel lens for use as a 2D concentrator.

### DESCRIPTION OF EMBODIMENTS

In the following description, reference is made to the accompanying drawings, which form a part hereof and which illustrate several embodiments of the present invention. The drawings and the preferred embodiments of the invention are presented with the understanding that the present invention is susceptible of embodiments in many different forms and, therefore, other embodiments may be utilized and structural, and operational changes may be made, without departing from the scope of the present invention.

FIG. 1 illustrates a solar collector that includes a concentrator (120) and a light receiver (130). In this figure, the light receiver (130) includes one concave photovoltaic cell structure and reflecting surfaces (111) appended to the concave photovoltaic cell structure. The concave photovoltaic cell structure consists of a curved photovoltaic cell (105) or a plurality of flat photovoltaic cells (505) assembled to form a concave shape. The flat photovoltaic cells (505) may have any flat shape, such as triangular, pentagonal, and hexagonal.

The reflecting surfaces (111) are attached to the photovoltaic cell structure and are oriented to reflect light onto the photovoltaic cell structure. The combination of photovoltaic cell structure and reflecting surfaces form a concave light-receiving surface (125) (represented by the dashed line in FIG. 1) that is more or less continuous.

The concentrator (120) focuses or concentrates light roughly to a point or to a line. As used herein a concentrator is for concentrating sunlight. The concentrator may be reflective, such as a parabola, or refractive, such as lens or Fresnel lens. If the concentrator (120) is reflective, then in cross sectional view, it preferably has a parabolic shape. The presence of mirrors (110) makes the manufacture of the concentrator (120) much simpler because it potentially widens the capture area significantly beyond a focal line, so that the concentrator (120) may not be ideally shaped. The solar collector may also employ a surrounding container (1305), which is transparent at least at the top portion to allow light to enter the container (1305) and strike the concentrator (120).

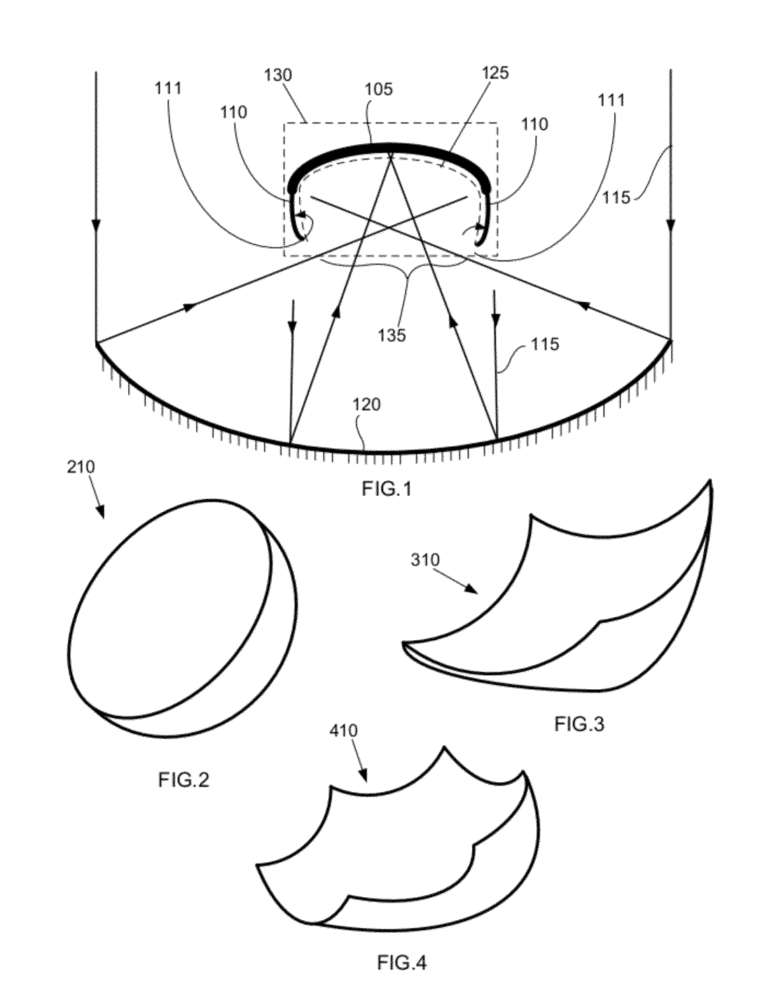

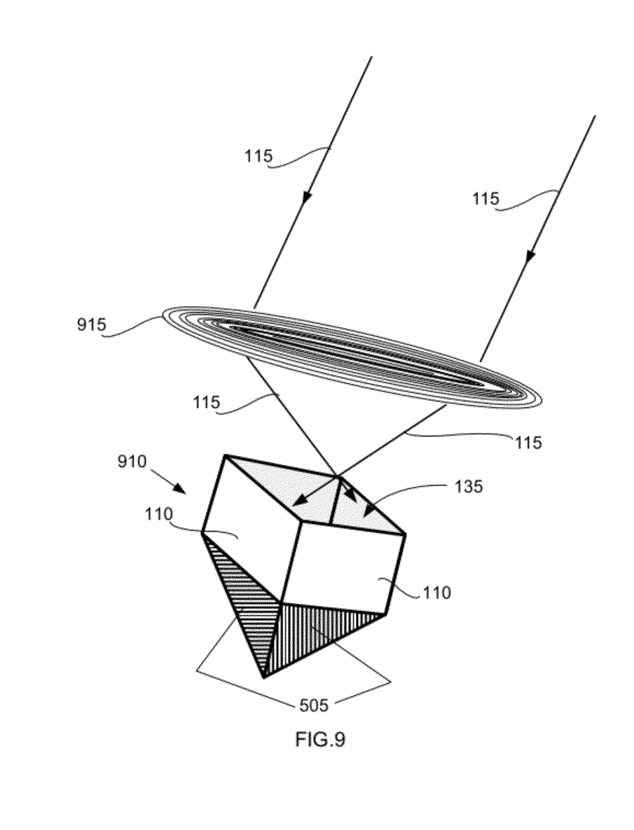

If the solar collector is to focus or concentrate light into an approximate point, then it is conventionally called a three-dimensional (3D) concentrator. Exemplary 3D concentrators are shown in FIG. 2: a circular 3D concentrator (210); in FIG. 3: square 3D concentrator (310); and in FIG. 4: hexagonal 3D concentrator (410). The concentrator (120) in each of these figures is reflective and its shape is preferably a circular parabola. The 3D concentrator may also be refractive. FIG. 9 illustrates a 3D refractive concentrator that is a circular Fresnel lens (915) whose groove pattern is formed with circular lines.

If the concentrator is to focus or concentrate light into an approximate line, then it is customary to call it a two-dimensional (2D) concentrator, which is also known in the art as a linear concentrator. Examples of linear concentrators include a parabolic trough as shown in FIG. 15 and a linear Fresnel lens (1910), shown in FIG. 19, whose groove pattern is formed with straight lines.

The light receiver (130) is indicated by a first dashed enclosure designated with that reference number.

The concave light-receiving surface is the curved photovoltaic cell (105) in FIG. 1. However the best efficient solar cells available today are flat and fragile, not suitable to be bent into a curved shape. Thus, a partial polygon shape in cross section, which shape is created by two or more flat photovoltaic cells (505) is a preferred embodiment and is next best to a continuous curved shape of the curved photovoltaic cell (105).

FIG. 5 depicts an alternative light-receiving surface (525), which is formed by two photovoltaic cells (for liner concentrator) or more photovoltaic cells (for 3D concentrator). The cross-sectional shape of the concave light-receiving volume defined by the alternative light-receiving surface (525) and its appended mirrors when virtually closed at the bottom may vary.

For a linear concentrator, a light-receiving volume or space is created by the imaginary closure of dashed line representing the concave light-receiving surface (125). This light-receiving volume is a polygon rod shape (1210), as illustrated in FIG. 15.

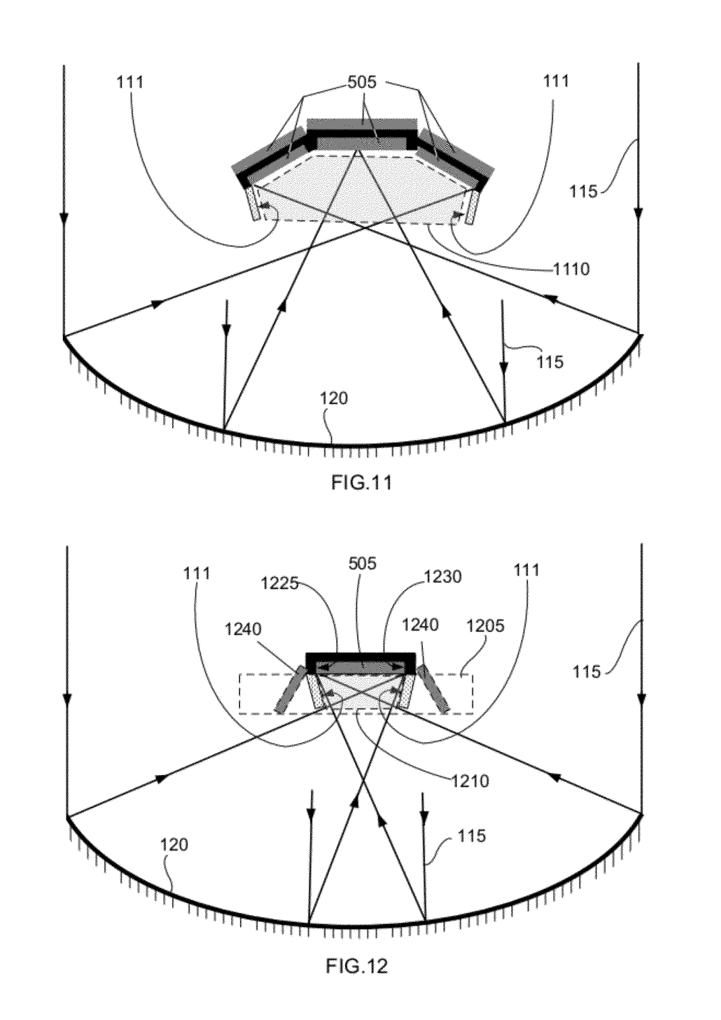

FIG. 11 illustrates a light-receiving volume having a hexagon polygon rod shape (1110). The concave light receiving surface is consisting of 3 photovoltaic cells.

FIG. 12 is a cross-sectional view of a solar collector with a photovoltaic cell with appended mirrors. With properly oriented mirrors and properly selected light entrance, the flat photovoltaic cells (505) and their two mirror images (1240) form a virtual concave light receiving surface equivalent to FIG. 11.

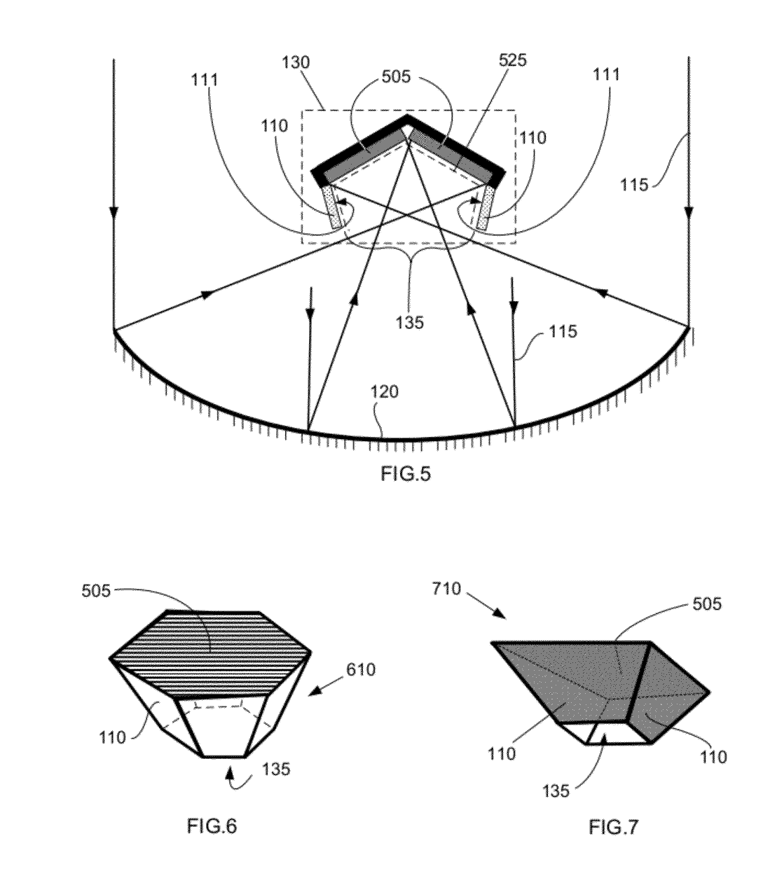

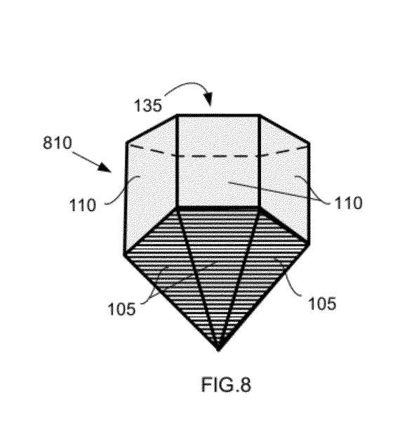

For a 3D concentrator, the alternative light-receiving surface (525) when closed at the bottom may be described as being in the shape of a polyhedron. FIG. 6, FIG. 7, FIG. 8 and FIG. 9 illustrate polyhedron solar cell configurations. FIG. 6 illustrates a hexagonal-base polyhedron receiving volume (610), FIG. 7 illustrates a rectangular-base polyhedron receiving volume (710), FIG. 8 illustrates an alternative hexagonal-base polyhedron receiving volume (810) and FIG. 9 illustrates an alternative rectangular-base polyhedron receiving volume (910).

The light receiver (130) includes a photovoltaic cell structure and reflecting surfaces attached to the photovoltaic cell structure. Attached to the photovoltaic cell structure means being either directly connected to the flat photovoltaic cells (505) or to the curved photovoltaic cell (105), or indirectly connected when attached to something, such as a frame that is physically connected to the flat photovoltaic cells (505) or to the curved photovoltaic cell (105).

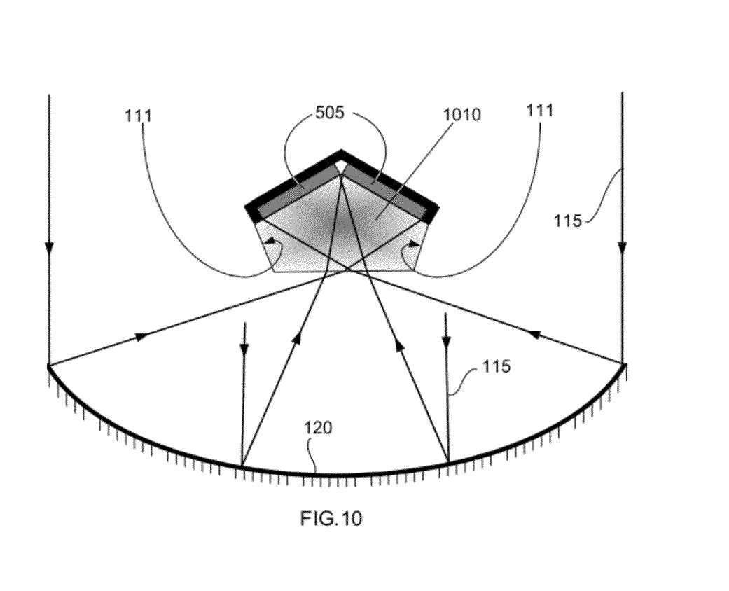

The reflecting surfaces (111) may be a mirrored wall of a mirror. Alternatively, as shown in FIG. 10, each of the reflecting surfaces (111) may be a side wall of a reflecting prism (1010), which is preferably reflective by total internal reflection, but may also be mirrored with, for example, silver.

The assembly of the curved photovoltaic cell (105) or the flat photovoltaic cells (505) and each of the reflecting surfaces (111) effectively defines a light-receiving space, with one side of concave light-receiving space being an open end (135), or a transparent reflecting prism wall, allowing the sunlight (115) to enter the concave light-receiving surface (125). For example, if the reflecting surfaces (111) are mirrors (110), then the bottom wall of the concave light-receiving surface (125) is imaginary, connecting the bottom end of the mirrors (110). One or more photovoltaic cells may also be placed atop the light receiver (130) to capture light directly and not reflected from the concentrator (120).

The concave light-receiving space is, effectively, the volume into which concentrated light from the concentrator (120) is received. This is best shown in FIG. 15 where two arrows represent sunlight (115) that reflects off the ends of the elongated light-concentrator (1535) to the bottom of the reflecting surfaces (111). Once the concentrated light is focused into the polygon rod shape (1210) of the concave light-receiving space, any concentrated light that does not directly impinge on the curved photovoltaic cell (105) or the flat photovoltaic cells (505) is reflected towards them. Preferably, there is a plurality of photovoltaic cells extending along a length (1510) of the focus of the concentrator (120). The photovoltaic cell and its mirror images form a concave light-receiving surface that ensures concentrated light impinges more or less normally to the photovoltaic cells.

FIG. 8 and FIG. 9 illustrate alternative embodiments of a 3D version of light receiver. FIG. 8 represents a 3D version of light receiver having the alternative hexagonal-base polyhedron receiving volume (810) with triangular photovoltaic cells. FIG. 9 illustrates a rectangular-base polyhedron receiving volume (910) with triangular photovoltaic cells. The open end (135) is at the bottom of FIG. 6 and FIG. 7 and at the top of FIG. 8 and FIG. 9.

Sunlight (115) is reflected off the concentrator (120) into the open end (135) of the light receiver (130) at the bottom of the light receiver (130) as shown in FIG. 1. Each of the mirrors (110) has a wall that is one of the reflecting surfaces (111). This wall reflects sunlight (115) that might otherwise miss the photovoltaic cell (105). The reflecting surfaces (111) are oriented to reflect sunlight (115) onto the concave light-receiving surface (125) and towards the photovoltaic cell (105).

As shown in FIG. 15, an elongated light-concentrator (1535) may be linear so as to cause the concentrated light to focus near or within the concave light-receiving surface (125). The concentrator's elongate shape is in the form of an open-top trough that will focus incoming sunlight into an approximate line that is near or within the polygon rod shape (1210) of the concave light-receiving space. The focus of the concentrator may be below the polygon rod shape (1210) of the concave light-receiving space and the light will still enter the polygon rod shape (1210) of the concave light-receiving space after merging to the focus. The polygon rod shape (1210) of the concave light-receiving space is also elongated, with an open end to allow the concentrated light to enter the polygon rod shape (1210) of the concave light-receiving space.

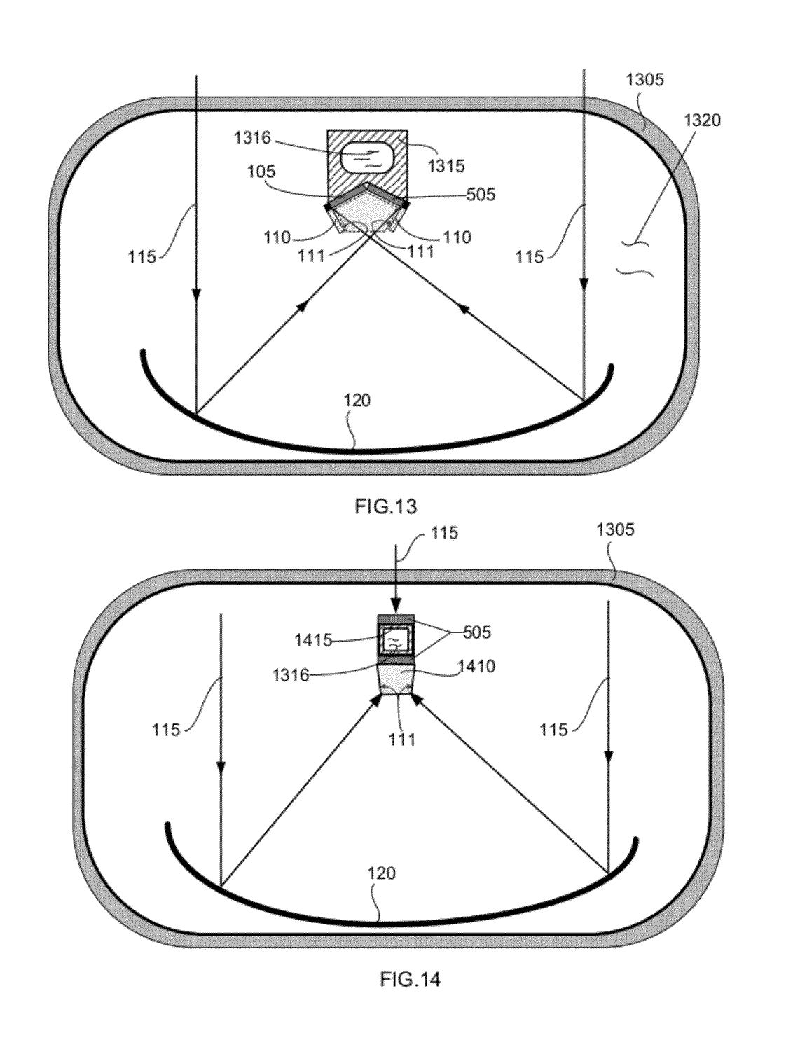

FIG. 13 and FIG. 14 illustrate a solar collector also including a heat pipe attached to the light receiver. FIG. 13 includes the light receiver (130) shown in FIG. 5. In FIG. 13, a first type of heat pipe (1315) has a bottom wall in an inverted V-shape to correspond to the top surface or upper face of the light receiver (130). Full contact with the light receiver (130) enables the first type of heat pipe (1315) to remove heat from each of the flat photovoltaic cells (505) and potentially recover this heat for other useful purposes. FIG. 14 illustrates a second type of heat pipe (1415) with a rectangular cross-section and a flat or planar face.

A heat pipe is a closed system that contains a working fluid (1316) that carries the heat away from the photovoltaic cells. A second reflecting prism (1410) has a trapezoid cross-section, which is optically equivalent to that of FIG. 12, because it also generates mirror images of the photovoltaic cell, and together with the real photovoltaic cell forms a “virtual” concave light receiving surface equivalent to FIG. 11.

The solar collector may further include a container (1305) encasing the concentrator (120) and the light receiver (130). The top of the container (1305) allows light to enter and illuminate the concentrator (120). It may simply be transparent or may be in the form of a Fresnel lens to replace the reflective concentrator in the bottom, in which case the light receiver (130) is inverted to receive light from above as illustrated in FIG. 9. The container (1305) may be sealed and may be held under a vacuum or may hold an insulating gas (1320), such as xenon or krypton.

A sun-tracking device may be used to rotate this solar collector to obtain maximum amount of sunlight.

An embodiment of the device disclosed herein may be considered an improvement to a solar collector that includes a linear light-concentrator as shown in FIG. 15, a light-receiver, a heat pipe, and a sealed container. The linear light-concentrator has a length (1510) and a width (1520) and focuses light from the sun towards a photovoltaic cell (105) and in a focal line. The improvement is a mirrored structure (1205), appended to the photovoltaic cell structure. The mirrored structure (1205) creates images (1240) of the photovoltaic cells, as shown in FIG. 12. These images (1240) and the photovoltaic cell form a concave-light-receiving surface which is equivalent to that in FIG. 11.

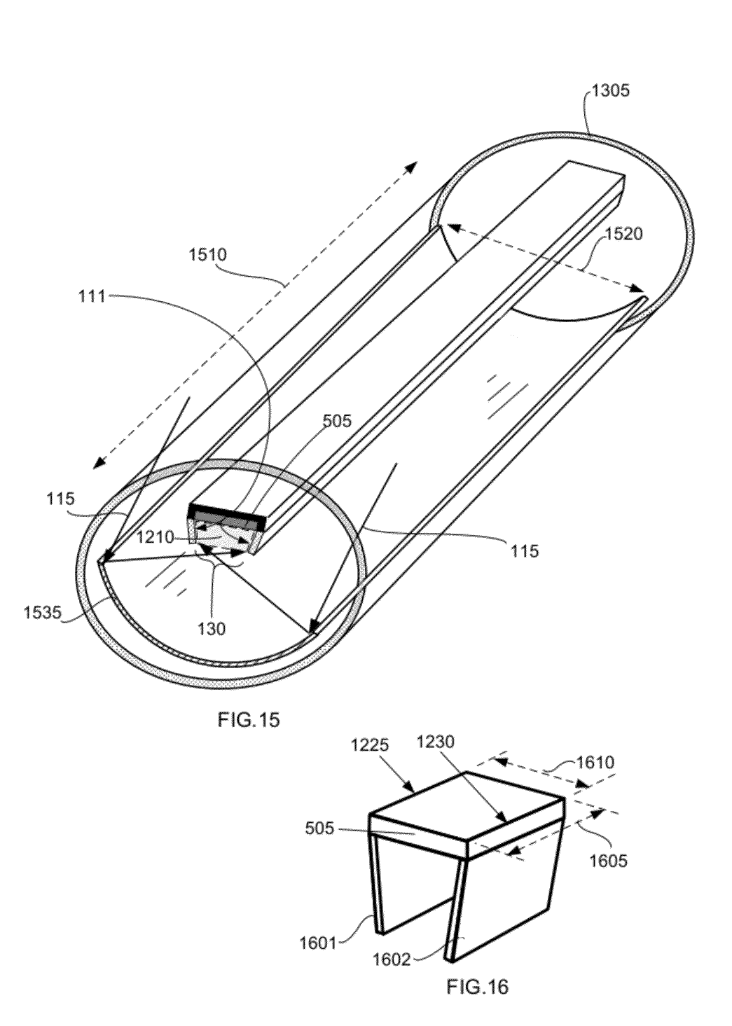

FIG. 16 illustrates a perspective view of a mirrored structure extending from one of the flat photovoltaic cells (505). The mirrored structure includes two mirrors: a first mirror (1601) and a second mirror (1602). It has a cell length (1605) and a cell width (1610) and thus a first end (1225) and a second end (1230) across the cell width (1610) of the photovoltaic cell. The first mirror (1601) extends downwardly from the first end (1225) and extends along the cell length (1605) of the photovoltaic cell; and the second mirror (1602) extends downwardly from the second end (1230) along the cell length (1605) of the photovoltaic cell. Typically, multiple flat photovoltaic cells (505) would be connected together along the cell length (1605) and would have a linear light-concentrator as shown in FIG. 15. In that case, the first mirror (1601) and the second mirror (1602) would reflect light onto each of the flat photovoltaic cells (505) along the length (1510) of the elongated light-concentrator (1535), and create a “virtual” polygon concave-light-receiving volume, also known as a “virtual” polygon rod shape (1110) as shown in FIG. 11. Thus, as shown in FIG. 15, the concentrator (1535) has focal line (indicated where the sunlight (115) arrows cross near or within the light receiver (130).

The mirrored structure (1205) may be a reflecting prism (1010) having two side reflecting walls, as in a linear solar collector, or 4 or more surrounding walls, as in 3D-array solar collector, each wall being one of the reflecting surfaces (111) that create mirror images of the photovoltaic cell, and these images of photovoltaic cells together with the actual photovoltaic cell form a “virtual” concave light-receiving surface.

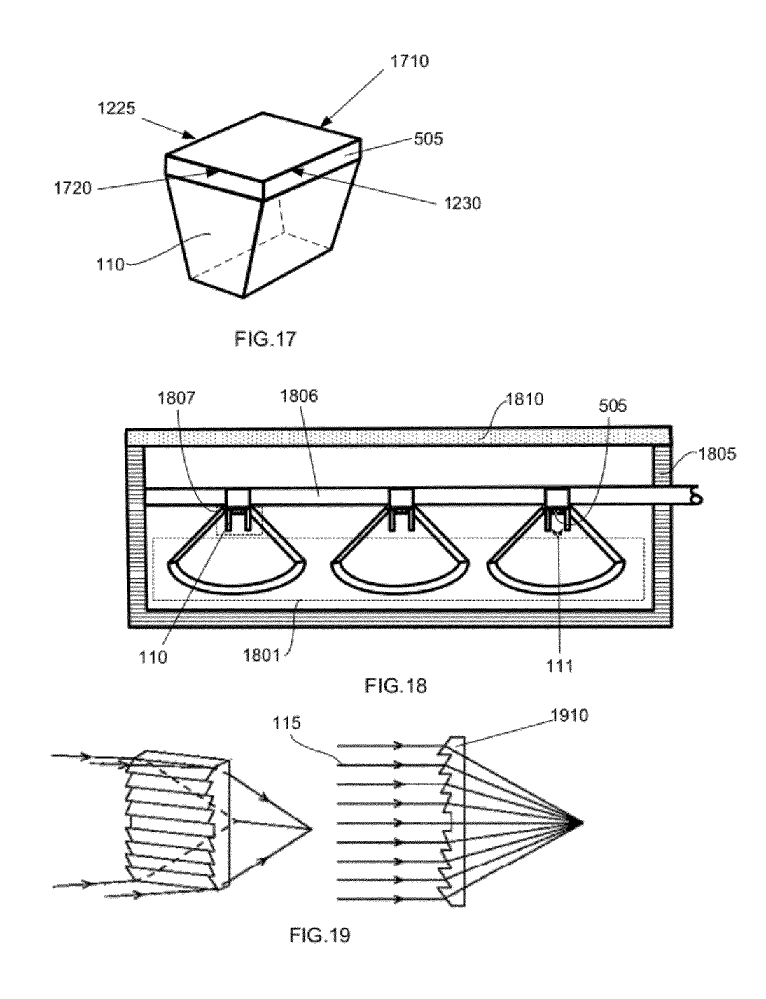

FIG. 17 illustrates a light receiver with mirrored structure, which could, alternatively, be replaced with a reflecting prism. This light receiver is preferably paired with a 3D concentrator. This mirrored structure includes 4 mirrors extending downwardly from all 4 edges of the flat photovoltaic cell. The photovoltaic cell and its mirrored images form a concave light-receiving surface, which when connected at the bottom end creates a virtual polyhedron-light-receiving volume.

FIG. 18 is a cross-sectional view of an embodiment of a solar collector that includes a sealed container with a transparent top (1810) and insulated walls (1805). The solar collector further includes an array of light-concentrators (1801) (shown within the dashed enclosure) mounted within the sealed container. The solar collector further includes a photovoltaic cell corresponding to each light concentrator in the array of light-concentrators (1801). Each photovoltaic cell is attached to a heat pipe (1806), or through an attachment if heat pipe surface if not flat. Each light-concentrator in the array of light-concentrators (1801) focuses light to a point or point like small area near one of the photovoltaic cells (505) corresponding to each said light concentrator. A mirrored structure (1807) (exemplified within the dashed enclosure) is appended to each of the photovoltaic cells (505).

Each of the flat photovoltaic cells (505) in this embodiment comprises ends: a first end (1225); a second end (1230); a third end (1710) and a fourth end (1720). Preferably, the mirrored structure (1807) includes mirrors (110) extending downwardly from the ends, that is, a mirror extending downwardly from the first end (1225); the second end (1230); the third end (1710) and the fourth end (1720). Each of the flat photovoltaic cells (505) and its images (1240) within the appended mirrored structure (1807) create a concave-light-receiving surface.

In this embodiment, each mirrored structure may be a reflecting prism. Each reflecting prism has walls that reflect light on one of the flat photovoltaic cells (505) and has the same function as mirrors.

The above-described embodiments including the drawings are examples of the invention and merely provide illustrations of the invention. Other embodiments will be obvious to those skilled in the art. Thus, the scope of the invention is determined by the appended claims and their legal equivalents rather than by the examples given.

### INDUSTRIAL APPLICABILITY

The invention has application to the renewable energy industry.

What is claimed is:

1. A solar collector comprising:
a concentrator that focuses sunlight to create concentrated light; and
a light receiver, the light receiver comprising a concave photovoltaic cell structure and reflecting surfaces attached to the concave photovoltaic cell structure, said reflecting surfaces oriented to reflect light onto the photovoltaic cell structure.

2. The solar collector of claim 1, wherein when the concave photovoltaic cell structure consists of a curved photovoltaic cell.

3. The solar collector of claim 1, wherein the photovoltaic cell structure consists of a plurality of flat photovoltaic cells assembled to form a concave shape.

4. The solar collector of claim 1, wherein the concave photovoltaic cell structure is a formed by a photovoltaic cell and its mirror images created by the reflecting surfaces.

5. The solar collector of claim 1, wherein each reflecting surface is a mirrored wall of a mirror.

6. The solar collector of claim 1, wherein each reflecting surface is a side-wall of a reflecting prism, each said side-wall reflective by total internal reflection.

7. The solar collector of claim 1, further comprising a heat pipe attached to the photovoltaic cells.

8. The solar collector of claim 1, further comprising a container encasing the concentrator and the light receiver, said container allows light to enter and illuminate the concentrator.

9. The solar collector of claim 8, wherein said container is sealed and is held under a vacuum.

10. The solar collector of claim 8, wherein said container is sealed and comprises an insulating gas.

11. An improvement to a solar collector, the solar collector comprising a linear light-concentrator having a length and a width, the linear light-concentrator focuses sunlight towards a photovoltaic cell and in a focal line, the improvement comprising:
a mirrored structure appended to the photovoltaic cell, said mirrored structure creating images of the photovoltaic cell, said images and the photovoltaic cell form a concave-light-receiving surface, the photovoltaic cell and mirrored structure comprising a light receiver.

12. The improvement of claim 11, wherein the photovoltaic cell comprises a first end and a second end, the mirrored structure comprising a first mirror extending downwardly from the first end along the length of the linear light-concentrator; and a second mirror extending downwardly from the second end along the length of the linear light-concentrator, said first mirror and said second mirror reflecting light onto the photovoltaic cell.

13. The improvement of claim 11, wherein the mirrored structure comprises a reflecting prism, the reflecting prism comprising walls that reflect light onto the photovoltaic cell.

14. An improvement to a solar collector, the solar collector comprising a light-concentrator and a photovoltaic cell, the light concentrator focuses light to a point or point like small area near the photovoltaic cell, the improvement comprising:
a mirrored structure appended to the photovoltaic cell, said mirrored structure creates images of the photovoltaic cell, and these images together with the photovoltaic cell form a concave-light-receiving surface, the photovoltaic cell and mirrored structure comprising a light receiver.

15. The improvement of claim 14, wherein photovoltaic cell comprises edges, the mirrored structure comprising a mirror extending downwardly from each edge, each said mirror reflecting light onto the photovoltaic cell adjacent thereto.

16. The improvement of claim 14, wherein each mirrored structure comprises a reflecting prism, the reflecting prism comprising walls that reflect light onto the photovoltaic cell.

17. The improvement of claim 14, further comprising a container encasing a plurality of light receivers and concentrators, said container allowing light to enter and illuminate the concentrators.

18. The improvement of claim 17, further comprising a heat pipe attached to each photovoltaic cell in the container.

19. The improvement of claim 17, wherein said container is sealed and is held under a vacuum.

20. The improvement of claim 17, wherein said container is sealed and comprises an insulating gas.
